(19) United States
(12) Patent Application Publication
(10) Pub. No.: US 2023/0154753 A1
(43) Pub. Date: May 18, 2023

(54) Patterned Semiconductor Device and Method

(71) Applicant: Taiwan Semiconductor Manufacturing Co., Ltd., Hsinchu (TW)

(72) Inventors: Jung-Hau Shiu, New Taipei City (TW); Ching-Yu Chang, Taipei City (TW); Wei-Ren Wang, New Taipei City (TW); JeiMing Chen, Tainan City (TW)

(21) Appl. No.: 17/686,184

(22) Filed: Mar. 3, 2022

Related U.S. Application Data
(60) Provisional application No. 63/264,197, filed on Nov. 17, 2021.

(51) Int. Cl. H01L 21/033; H01L 21/311

(52) U.S. Cl. CPC H01L 21/0337; H01L 21/31116; H01L 21/31144

(57) ABSTRACT

Methods of patterning semiconductor devices and semiconductor devices formed by the same are disclosed. In an embodiment, a method includes forming a first dielectric layer over a semiconductor substrate; forming a first hard mask layer over the first dielectric layer; etching the first hard mask layer to form a first opening exposing a top surface of the first dielectric layer; performing a plasma treatment process on the top surface of the first dielectric layer and a top surface of the first hard mask layer; after performing the plasma treatment process, selectively depositing a spacer on a side surface of the first hard mask layer, the top surface of the first dielectric layer and the top surface of the first hard mask layer being free from the spacer after selectively depositing the spacer; and etching the first dielectric layer using the spacer as a mask.

### PRIORITY CLAIM AND CROSS-REFERENCE

This application claims the benefit of U.S. Provisional Application No. 63/264,197, filed on Nov. 17, 2021, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 3A, 3B, 4A, 4B, 5A, 5B, 6A, 6B, 7A, 7B, 8A, 8B, 9A, 9B, 10A, 10B, 11A, 11B, 12A, and 12B illustrate cross-sectional views and top-down views of intermediary stages of manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide improved methods of patterning target layers in semiconductor devices and semiconductor devices formed by the same. The methods include performing a selectivity-increasing process on a patterned layer and an underlying dielectric layer and selectively depositing spacers along sidewalls of the patterned layer. The selectivity-increasing process may include performing a plasma treatment on surfaces of the patterned layer and the underlying dielectric layer, forming self-assembled monolayers (SAMs) over the patterned layer and the underlying dielectric layer, or the like. Following the selectivity-increasing process, the spacers may be selectively deposited along surfaces of the patterned layer that were not subjected to the selectivity-increasing process, without being deposited along surfaces of the patterned layer that were subjected to the selectivity-increasing process. Specifically, the selectivity-increasing process may be performed on top surfaces of the patterned layer and the underlying dielectric layer, and the spacers may be selectively deposited along sidewalls of the patterned layer. Forming the spacers by a selective deposition process allows for etch processes to be eliminated, which reduces costs and prevents damage to the underlying dielectric layer and other underlying layers. This reduces device defects.

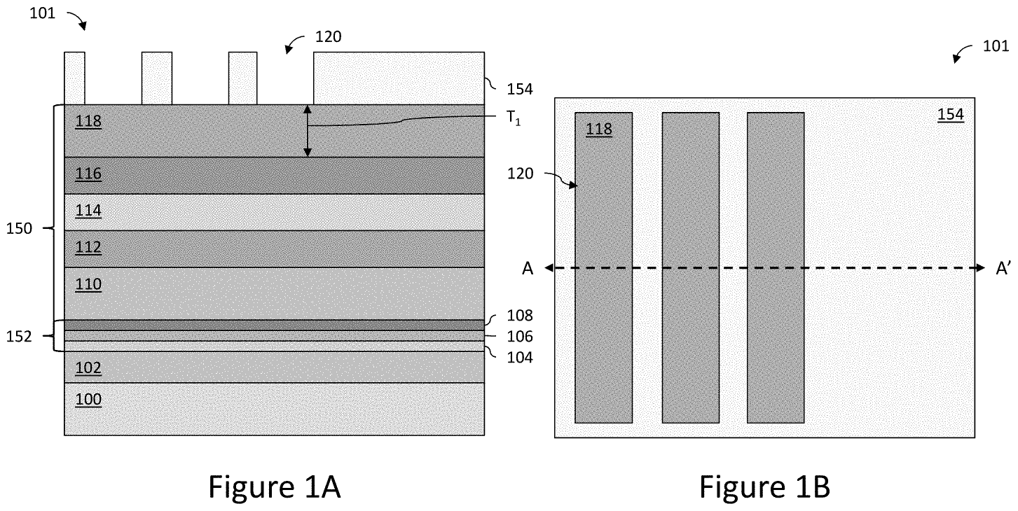

FIGS. 1A through 12B illustrate cross-sectional views and top-down views of intermediate stages in the formation of features in a target layer 102 of a semiconductor device 101, in accordance with some embodiments. In FIGS. 1A through 12B, figures ending with an “A” designation are illustrated along reference cross-section A-A illustrated in FIG. 1B, and Figures ending with a “B” designation are illustrated in a top-down view. The target layer 102 is a layer in which a plurality of patterns is to be formed. In some embodiments, the semiconductor device 101 may be processed as part of a larger wafer. In such embodiments, after various features of the semiconductor device 101 are formed (e.g., active devices, interconnect structures, and the like), a singulation process may be applied to scribe line regions of the wafer in order to separate individual semiconductor dies from the wafer (also referred to as singulation).

FIGS. 1A and 1B illustrate a multi-layer film stack 150 formed over a semiconductor substrate 100. The multi-layer film stack 150 may include the target layer 102, an etch stop structure 152, a first dielectric layer 110, a second dielectric layer 112, a first hard mask layer 114, a third dielectric layer 116, and a second hard mask layer 118. The etch stop structure 152, the first dielectric layer 110, the second dielectric layer 112, the first hard mask layer 114, and the third dielectric layer 116 may be optional layers, any of which may be omitted in some embodiments. The layers of the multi-layer film stack 150 may be stacked in any desired order, may be duplicated, or may be otherwise repeated, in accordance with some embodiments.

The semiconductor substrate 100 may be formed of a semiconductor material such as silicon, doped or un-doped, or an active layer of a semiconductor-on-insulator (SOI) substrate. The semiconductor substrate 100 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; combinations thereof; or the like. Other substrates, such as multi-layered or gradient substrates, may also be used. Devices, such as transistors, diodes, capacitors, resistors, and the like, may be formed in and/or on an active surface of the semiconductor substrate 100. In some embodiments, the target layer 102 may be a semiconductor substrate. For example, in some embodiments, the target layer 102 may be a semiconductor substrate used to form fin field-effect transistors (FinFETs), nanostructure field effect transistors (nano-FETs), or the like. In such embodiments, the semiconductor substrate 100 may be omitted.

The target layer 102 may be a layer in which a pattern is to be formed. In some embodiments, the target layer 102 may be a conductive layer, a dielectric layer, a semiconductor layer, or the like. In embodiments in which the target layer 102 is a conductive layer, the target layer may be a metal layer, a polysilicon layer, or the like. The target layer 102 may be deposited by physical vapor deposition (PVD), chemical vapor deposition (CVD) (e.g., blanket deposition or the like), or the like. The conductive layer may be patterned according to the processes described below to form metal gates (e.g., in a cut metal gate process), conductive lines, conductive vias, dummy gates (e.g. for replacement gates in FinFETs, nano-FETs, or the like), or the like.

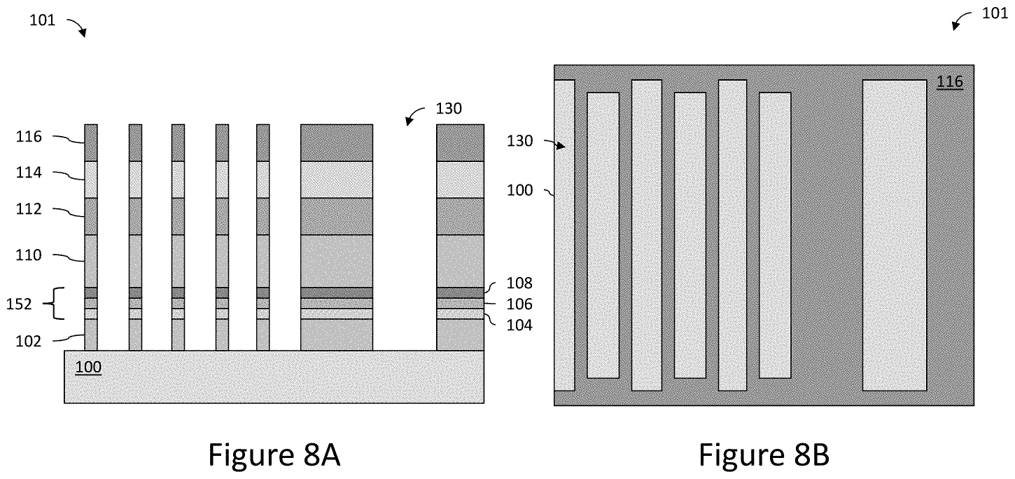

In embodiments in which the target layer 102 is a dielectric layer, the target layer 102 may be an inter-metal dielectric layer, an inter-layer dielectric layer, a passivation layer, or the like. The target layer 102 may be a material having a low dielectric constant (e.g., a low-k material). For example, the target layer 102 may have a dielectric constant lower than 3.8, lower than 3.0, or lower than 2.5. The target layer 102 may be a material having a high dielectric constant, such as a dielectric constant higher than 3.8. The target layer 102 may be deposited by CVD, atomic layer deposition (ALD), or the like. One or more openings (such as openings 130, discussed below with respect to FIGS. 8A and 8B) may be patterned in the target layer 102 according to the processes described below and conductive lines, conductive vias, or the like may be formed in the openings in the target layer 102.

In embodiments in which the target layer 102 is a semiconductor material, the target layer 102 may be formed of silicon, silicon germanium, or the like. In some embodiments, the target layer 102 may be formed of a crystalline semiconductor material such as crystalline silicon, crystalline silicon carbide, crystalline silicon germanium, a crystalline III-V compound, or the like. In some embodiments, openings (such as openings 130, discussed below with respect to FIGS. 8A and 8B) may be patterned in the target layer 102 according to the processes described below and shallow trench isolation (STI) regions may be formed in the openings in the target layer 102. Semiconductor fins may protrude from between neighboring STI regions and source/drain regions may be formed in the semiconductor fins. The semiconductor fins may include material of the target layer 102 remaining after forming the openings in the target layer 102. Gate dielectric layers and gate electrodes may be formed over channel regions in the semiconductor fins, thereby forming semiconductor devices such as FinFETs, nano-FETs, or the like.

Although FIGS. 1A and 1B illustrate the target layer 102 as being in physical contact with the semiconductor substrate 100, any number of intervening layers may be disposed between the target layer 102 and the semiconductor substrate 100. Such intervening layers may include an inter-layer dielectric (ILD) layer, which may include a low-k dielectric and may include contact plugs formed therein; other inter-metallic dielectric (IMD) layers having conductive lines and/or vias formed therein; one or more intermediary layers (e.g., etch stop layers, adhesion layers, or the like); combinations thereof; or the like. In some embodiments, an etch stop layer may be disposed directly under the target layer 102. The etch stop layer may act as a stop for an etching process subsequently performed on the target layer 102 (e.g., the etching process described below with respect to FIGS. 8A and 8B). The materials and processes used to form the etch stop layer may depend on the material of the target layer 102. In some embodiments, the etch stop layer may be formed of silicon nitride, SiON, SiCON, SiC, SiOC, SiCₓN_{y}, SiOₓ, other dielectrics, combinations thereof, or the like. The etch stop layer may be deposited by CVD, ALD, plasma-enhanced chemical vapor deposition (PECVD), low-pressure CVD (LPCVD), PVD, or the like.

The etch stop structure 152 is formed over the target layer 102. The etch stop structure 152 may include a dielectric material, such as a nitride, a silicon-carbon based material, a carbon-doped oxide, or a metal-containing dielectric. In some embodiments, the etch stop structure 152 may include SiCN, SiOCN, SiOC, AlOx, AN, AlCN, combinations or multiple layers thereof, or the like. The etch stop structure 152 may be deposited by CVD, ALD, PVD, or the like. The etch stop structure 152 may be a single layer formed of a homogeneous material, or a composite layer including a plurality of dielectric sub-layers. In the embodiment illustrated in FIGS. 1A and 1B, the etch stop structure 152 includes a first etch stop layer 104, a second etch stop layer 106, and a third etch stop layer 108. In some embodiments, the first etch stop layer 104 may include aluminum nitride (AlN), the second etch stop layer 106 may include oxygen-doped silicon carbide (ODC), and the third etch stop layer 108 may include aluminum oxide (AlOx).

The first dielectric layer 110 is formed over the etch stop structure 152. In some embodiments, the first dielectric layer 110 may be an anti-reflective coating (ARC), which may aid in the exposure and focus of overlying photoresist layers during patterning of the overlying photoresist layers. The first dielectric layer 110 may be a low-k dielectric material having a dielectric constant (k value) lower than 3.8, lower than 3.0, lower than 2.5, or the like. In some embodiments the first dielectric layer 110 may include SiOCH; other carbon-doped oxides; extremely low-k dielectric materials, such as porous carbon-doped silicon dioxide; silicon oxide; silicon nitride; SiON; a polymer, such as polyimide; combinations or multiple layers thereof; or the like. In some embodiments, the first dielectric layer 110 may be is substantially free from nitrogen, and may be referred to as a nitrogen-free ARC (NFARC). The first dielectric layer 110 may be deposited through a process such as spin-on coating, CVD, or the like.

The second dielectric layer 112 is formed over the first dielectric layer 110. The second dielectric layer 112 may be formed from a silicon oxide material. In some embodiments, the second dielectric layer 112 may be an oxide material, such as silicon oxide formed using a precursor such as tetraethyl orthosilicate (TEOS); other oxides; silicon nitride; other nitrides; combinations or multiple layers thereof, or the like. The second dielectric layer 112 may be deposited by CVD, ALD, PVD, spin-on coating, or the like. Other processes and materials may be used. In some embodiments, the second dielectric layer 112 may be an ARC, such as an NFARC, and may be formed of any of the materials described above for the first dielectric layer 110.

The first hard mask layer 114 is formed over the second dielectric layer 112. The first hard mask layer 114 may be formed of a material that comprises a metal (e.g., titanium nitride, titanium, tantalum nitride, tantalum, a metal-doped carbide (e.g., tungsten carbide), or the like); a metalloid (e.g., silicon nitride, boron nitride, silicon carbide, or the like); silicon; combinations or multiple layers thereof; or the like. In some embodiments, a material composition of the first hard mask layer 114 may be selected to provide a high etch selectivity with an underlying layer, for example with respect to the second dielectric layer 112, the first dielectric layer 110, and/or the target layer 102. The first hard mask layer 114 may be deposited by CVD, PVD, ALD, or the like. In subsequent processing steps, a pattern is formed on the first hard mask layer 114 using an embodiment patterning process. The first hard mask layer 114 is then used as an etching mask for etching the underlying layers, where the pattern of the first hard mask layer 114 is transferred to the underlying layers.

The third dielectric layer 116 is formed over the first hard mask layer 114. The third dielectric layer 116 may be formed from a silicon oxide material. In some embodiments, the third dielectric layer 116 may be an oxide material, such as silicon oxide formed using a precursor such as TEOS; other oxides; silicon nitride; other nitrides; combinations or multiple layers thereof, or the like. The third dielectric layer 116 may be deposited by CVD, ALD, PVD, spin-on coating, or the like. Other processes and materials may be used. In some embodiments, the second dielectric layer 112 may be an ARC, such as an NFARC, and may be formed of any of the materials described above for the first dielectric layer 110. The first hard mask layer 114 and the third dielectric layer 116 may have different material compositions such that the first hard mask layer 114 and the third dielectric layer 116 can each be selectively etched.

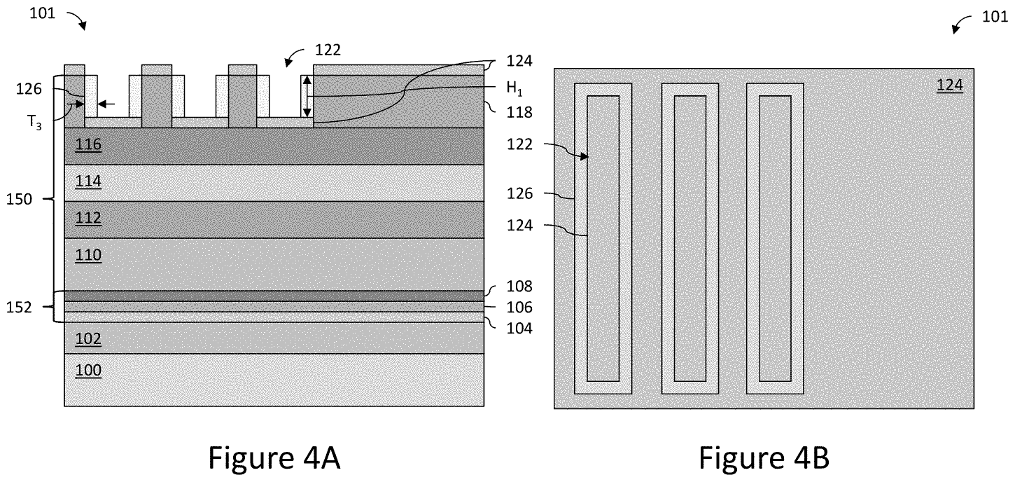

The second hard mask layer 118 is formed over the third dielectric layer 116. In some embodiments, the second hard mask layer 118 may comprise a patternable material, such as amorphous silicon (a-Si) which is deposited and subsequently patterned. The second hard mask layer 118 may be referred to as a mandrel layer, and may be subsequently patterned to form mandrels. In some embodiments, the second hard mask layer 118 may include silicon nitride, silicon oxide, or the like. The second hard mask layer 118 may be deposited by CVD, PVD, ALD, or the like. The second hard mask layer 118 may have a thickness T₁ ranging from about 10 nm to about 50 nm. Forming the second hard mask layer 118 with a thickness in the above-described range provides sufficient material to selectively deposit spacers on the second hard mask layer 118 (such as the spacers 126, discussed below with respect to FIGS. 4A and 4B), without negatively impacting subsequent etching of the second hard mask layer 118.

A patterned photoresist 154 is formed over the multi-layer film stack 150, on the second hard mask layer 118. The patterned photoresist 154 may be a single-layer photoresist, a tri-layer photoresist, or the like. The patterned photoresist 154 may be formed directly on (e.g., contacting) the second hard mask layer 118. The patterned photoresist 154 may be formed by spin-on coating or the like and may be exposed to patterned energy, such as patterned light, for patterning. In some embodiments, the patterned photoresist 154 includes a bottom anti-reflective coating (BARC) or an absorptive layer, such that only the patterned photoresist 154 is exposed to the patterned energy, without underlying layers of the multi-layer film stack 150 being exposed to the patterned energy or developed. The patterned photoresist 154 may be exposed to a developer to form openings 120 extending through the patterned photoresist 154 and exposing the second hard mask layer 118. In some embodiments, the openings 120 may have different sizes from one another.

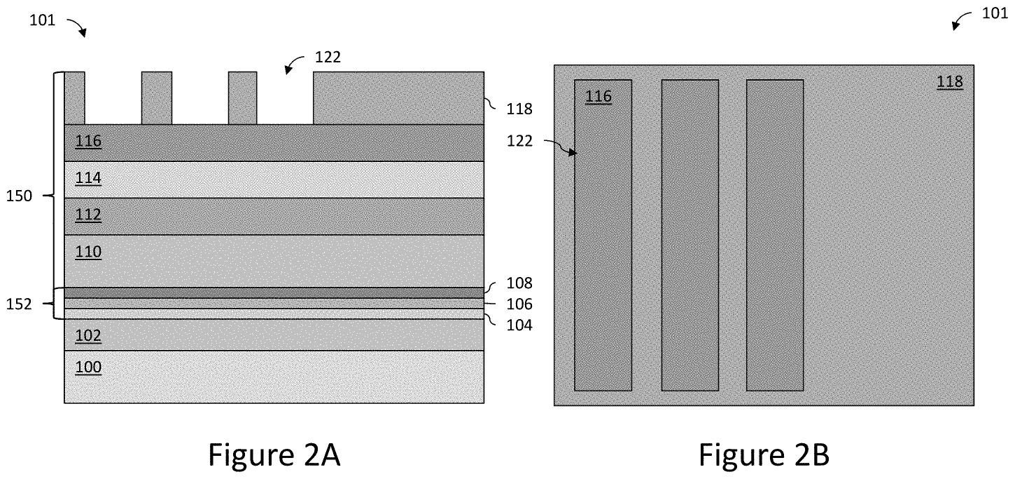

In FIGS. 2A and 2B, the second hard mask layer 118 is patterned by transferring the pattern of the patterned photoresist 154 (see FIGS. 1A and 1B) to the second hard mask layer 118. The second hard mask layer 118 may be patterned by an acceptable etch process, such as a dry etch, using the patterned photoresist 154 as an etch mask. In some embodiments, the dry etch is a plasma etch, which may be performed with etchants such as CF₄ gas in O₂. The patterning forms openings 122, which extend through the second hard mask layer 118 to expose the third dielectric layer 116. In some embodiments, the openings 122 may have different sizes from one another. The etch process may be anisotropic, such that the openings 122 extending through the second hard mask layer 118 have substantially the same sizes and shapes as the openings 120 extending through the patterned photoresist 154. The etch process may include processes such as reactive ion etching (RIE), neutral beam etching (NBE), or the like. Other etching techniques may be used in some embodiments. Once patterning of the second hard mask layer 118 is complete, remaining portions of the patterned photoresist 154 may be removed by, e.g., an etching process, an ashing process, combinations thereof, or the like.

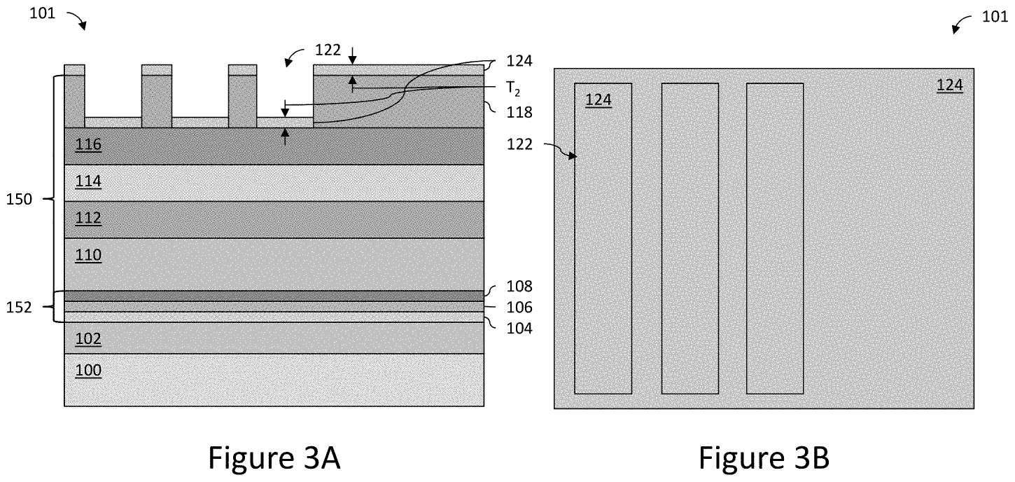

In FIGS. 3A and 3B, a selectivity-improving layer 124 is formed over the second hard mask layer 118 and the third dielectric layer 116. The top surfaces of the second hard mask layer 118 and the third dielectric layer 116 including the selectivity-improving layer 124 may be referred to as modified top surfaces. As illustrated in FIGS. 3A and 3B, the selectivity-improving layer 124 may be selectively deposited on top surfaces of the second hard mask layer 118 and exposed top surfaces of the third dielectric layer 116. The selectivity-improving layer 124 may be formed by performing a plasma treatment process on the top surfaces of the second hard mask layer 118 and the exposed top surfaces of the third dielectric layer 116. In some embodiments, the plasma treatment process may include an oxygen plasma treatment process, which is performed at a temperature ranging from about 100° C. to about 400° C., a pressure ranging from about 1 Torr to about 4 Torr, with a plasma power ranging from about 50 W to about 1000 W, and with a bias voltage ranging from about 10 V to about 100 V. The plasma treatment may be used to oxidize the top surfaces of the second hard mask layer 118 and the exposed top surfaces of the third dielectric layer 116. After the plasma treatment, the top surfaces of the second hard mask layer 118 and the exposed top surfaces of the third dielectric layer 116 may comprise OH-terminated silicon oxide. Side surfaces of the second hard mask layer 118 which were not exposed to the plasma treatment may comprise H-terminated silicon following the plasma treatment. The plasma treatment may be performed with an implantation angle substantially perpendicular to the top surfaces of the second hard mask layer 118 and the exposed top surfaces of the third dielectric layer 116 in order to prevent the side surfaces of the second hard mask layer 118 from being exposed to the plasma treatment.

The selectivity-improving layer 124 is then selectively deposited over the top surfaces of the second hard mask layer 118 and the exposed top surfaces of the third dielectric layer 116. In some embodiments, the selectivity-improving layer 124 may be formed from self-assembled monolayers (SAMs). In some embodiments, the selectivity-improving layer 124 may include SAMs having polar heads and large alkyl chains (e.g., having from 6 to 24 carbon atoms). For example, in some embodiments, the selectivity-improving layer 124 may be formed from precursors such as octadecyltrichlorosilane (CH₃(CH₂)₁₇SiCl₃, ODTS), 1-octadecanethiol (CH₃(CH₂)₁₇)SH), combinations thereof, or the like. In some embodiments, functional groups of the precursors, such as trichlorosilane groups in embodiments using ODTS, may react with hydroxyl groups in the top surfaces of the second hard mask layer 118 and the exposed top surfaces of the third dielectric layer 116 to form the selectivity-improving layer 124 on the top surfaces of the second hard mask layer 118 and the exposed top surfaces of the third dielectric layer 116. The selectivity-improving layer 124 may be deposited to a thickness T₂ ranging from about 1 nm to about 10 nm. As illustrated in FIGS. 3A and 3B, the selectivity-improving layer 124 is selectively deposited on the top surfaces of the second hard mask layer 118 and the exposed top surfaces of the third dielectric layer 116, without being deposited on side surfaces of the second hard mask layer 118.

Forming the selectivity-improving layer 124 over the top surfaces of the second hard mask layer 118 and the exposed top surfaces of the third dielectric layer 116 increases the selectivity of a deposition process subsequently performed to form spacers on the side surfaces of the second hard mask layer 118. This allows for etch processes performed on the spacers to be eliminated, which reduces costs and prevents damage to underlying layers, such as the third dielectric layer 116. This reduces device defects and improves device performance.

In FIGS. 4A and 4B, spacers 126 are formed in the openings 122 along side surfaces of the second hard mask layer 118. The side surfaces of the second hard mask layer 118 may be adjacent to the openings 122. The selectivity-improving layer 124 is unreactive to the deposition process used to deposit the spacers 126, such that the spacers 126 are selectively deposited along side surfaces of the second hard mask layer 118, which are free from the selectivity-improving layer 124, without the spacers 126 being deposited along the selectivity-improving layer 124 (e.g., along the top surfaces of the second hard mask layer 118 and the exposed top surfaces of the third dielectric layer 116). Specifically, the spacers 136 may be selectively deposited along the H-terminated silicon side surfaces of the second hard mask layer 118, without being deposited along the OH-terminated top surfaces of the second hard mask layer 118 and exposed top surfaces of the third dielectric layer 116.

The spacers 126 may be formed of metal-containing materials, such as metal oxides, metal nitrides, or the like. In some embodiments, the spacers 126 may be formed of titanium oxide (TiO₂), titanium nitride, aluminum oxide (Al₂O₃), or the like. The spacers 126 may be deposited by an ALD process in which a first precursor and a second precursor are alternately supplied to the semiconductor device 101. The first precursor may include titanium chloride (TiCl₄, TC), titanium dichloride diethoxide (TiCl₂(OC₂H₅)₂, TDD), titanium ethoxide (Ti(OC₂H₅)₄, TE), tetrakis(dimethylamido)titanium (TDMAT, ((CH₃)₂N)₄Ti), other titanium-containing precursors, aluminum-containing precursors, combinations thereof, or the like. The second precursor may include water, ozone, hydrogen peroxide, isopropanol, combinations thereof, or the like. The spacers 126 may be deposited to a thickness T₃ ranging from about 1 nm to about 10 nm. In the embodiment illustrated in FIGS. 4A and 4B, the spacers 126 may have heights less than a height of the second hard mask layer 118 (e.g., the thickness T₁). In some embodiments, the spacers 126 may have heights substantially equal to the height of the second hard mask layer 118. The spacers 126 may have heights Hi ranging from about 10 nm to about 50 nm. As illustrated in FIGS. 4A and 4B, the spacers 126 may be separated from the third dielectric layer 116 by the selectivity-improving layer 124.

Because the spacers 126 are selectively deposited only along sidewalls of the second hard mask layer 118, etching processes used to define the spacers 126 may be omitted. This reduces costs and reduces damage to underlying layers, such as the third dielectric layer 116. This further reduces device defects and improves device performance.

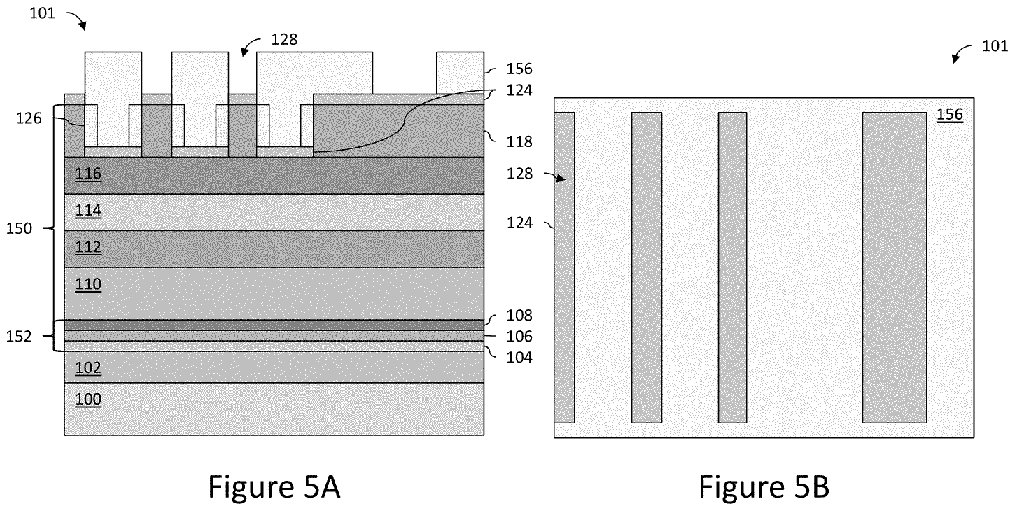

In FIGS. 5A and 5B, a second patterned photoresist 156 is formed over the spacers 126 and the selectivity-improving layer 124. The second patterned photoresist 156 may be a single-layer photoresist, a tri-layer photoresist, or the like. The second patterned photoresist 156 may be formed directly on (e.g., contacting) the spacers 126 and the selectivity-improving layer 124. The second patterned photoresist 156 may be formed by spin-on coating or the like and may be exposed to patterned energy, such as patterned light, for patterning. In some embodiments, the second patterned photoresist 156 includes a bottom anti-reflective coating (BARC) or an absorptive layer, such that only the second patterned photoresist 156 is exposed to the patterned energy, without underlying layers being exposed to the patterned energy or developed. The second patterned photoresist 156 may be exposed to a developer to form openings 128 extending through the patterned photoresist 154 and exposing the spacers 126 and the selectivity-improving layer 124. In some embodiments, the openings 128 may have different sizes from one another.

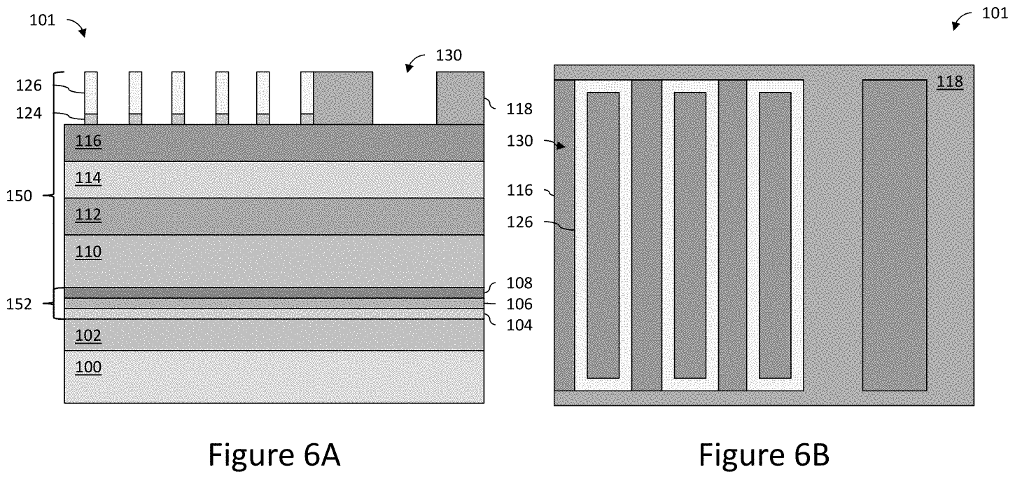

In FIGS. 6A and 6B, the second hard mask layer 118 and the selectivity-improving layer 124 are patterned by transferring the pattern of the second patterned photoresist 156 (see FIGS. 5A and 5B) to the second hard mask layer 118 and the selectivity-improving layer 124. The second hard mask layer 118 and the selectivity-improving layer 124 may be patterned by an acceptable etch process, such as a dry etch, using the second patterned photoresist 156 as an etch mask. In some embodiments, the dry etch is a plasma etch, which may be performed with etchants such as CF₄ gas in O₂. The patterning forms openings 130, which extend through the second hard mask layer 118, the selectivity-improving layer 124, and the spacers 126 to expose the third dielectric layer 116. In some embodiments, the openings 130 may have different sizes from one another. The etch process may be anisotropic, such that the openings 130 extending through the second hard mask layer 118, the selectivity-improving layer 124, and the spacers 126 have substantially the same sizes and shapes as the openings 128 extending through the second patterned photoresist 156. The etch process may include processes such as RIE, NBE, or the like. Other etching techniques may be used in some embodiments. Once patterning of the second hard mask layer 118 and the selectivity-improving layer 124 is complete, remaining portions of the second patterned photoresist 156 may be removed by, e.g., an etching process, an ashing process, combinations thereof, or the like.

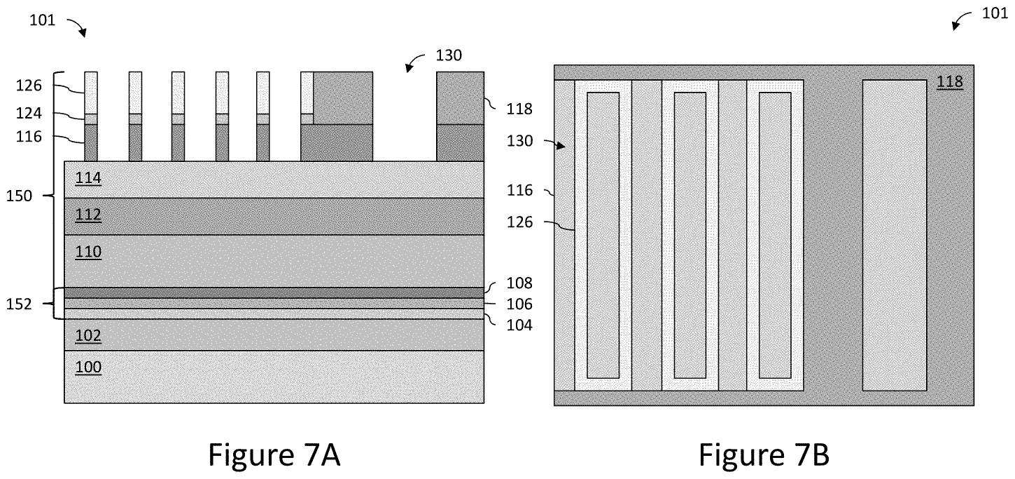

In FIGS. 7A and 7B, the third dielectric layer 116 is patterned by transferring the pattern of the spacers 126, the selectivity-improving layer 124, and the second hard mask layer 118 to the third dielectric layer 116. The third dielectric layer 116 may be patterned by an acceptable etch process, such as a dry etch, using the spacers 126, the selectivity-improving layer 124, and the second hard mask layer 118 as an etch mask. In some embodiments, the dry etch is a plasma etch. The patterning extends the openings 130 through the third dielectric layer 116 to expose the first hard mask layer 114. The etch process may be anisotropic, such that the openings 130 extending through the third dielectric layer 116 have substantially the same sizes and shapes as the openings 130 extending through the spacers 126, the selectivity-improving layer 124, and the second hard mask layer 118. The etch process may include processes such as RIE, NBE, or the like. Other etching techniques may be used in some embodiments.

FIGS. 8A and 8B illustrate the intermediate structures of FIGS. 7A and 7B after further processing. The pattern of the third dielectric layer 116 is transferred to the underlying layers (e.g., the first hard mask layer 114, the second dielectric layer 112, the first dielectric layer 110, the etch stop structure 152, and the target layer 102) to extend the openings 130 through the target layer 102. One or more etch processes may be used to extend the openings 130 through the first hard mask layer 114, the second dielectric layer 112, the first dielectric layer 110, the etch stop structure 152, and the target layer 102. For example, due to varying etch selectivities between the first hard mask layer 114, the second dielectric layer 112, the first dielectric layer 110, the etch stop structure 152, and the target layer 102, different etch chemistries may be used to transfer the pattern of the third dielectric layer 116 to different individual layers or sub-layers underlying the third dielectric layer 116. Although the third dielectric layer 116 and each of the first hard mask layer 114, the second dielectric layer 112, the first dielectric layer 110, and the etch stop structure 152 are illustrated as remaining above the target layer 102 in FIGS. 8A and 8B after the openings 130 are extended through the target layer 102, various etch processes used in transferring the pattern of the third dielectric layer 116 to the target layer 102 may consume at least partially the third dielectric layer 116, the first hard mask layer 114, the second dielectric layer 112, the first dielectric layer 110, and/or the etch stop structure 152. The one or more etch processes may be anisotropic etch processes, such as dry etch processes or the like.

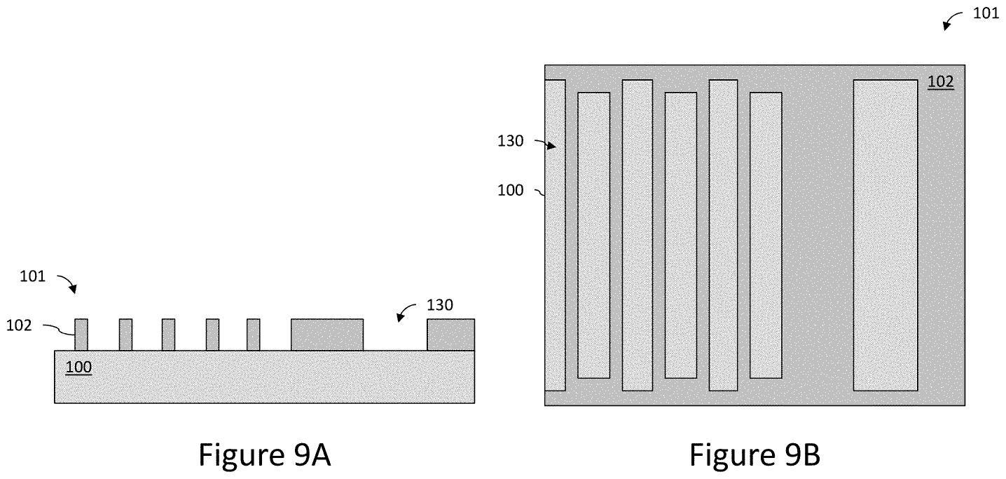

FIGS. 9A and 9B illustrate the intermediate structures of FIGS. 8A and 8B after further processing. Various etch processes and/or planarization processes may be used to remove any of the third dielectric layer 116, the first hard mask layer 114, the second dielectric layer 112, the first dielectric layer 110, and/or the etch stop structure 152 remaining over the target layer 102. In some embodiments, the third dielectric layer 116, the first hard mask layer 114, the second dielectric layer 112, the first dielectric layer 110, and/or the etch stop structure 152 may be removed by planarization processes, such as one or more chemical mechanical planarization (CMP) processes. In some embodiments, the third dielectric layer 116, the first hard mask layer 114, the second dielectric layer 112, the first dielectric layer 110, and/or the etch stop structure 152 may be removed by etch processes, such as wet etch processes, which may be isotropic.

Forming the selectivity-improving layer 124 over the second hard mask layer 118 and the third dielectric layer 116 helps to selectively deposit the spacers 126 only along side surfaces of the second hard mask layer 118, without depositing the spacers 126 along top surfaces of the second hard mask layer 118 or the third dielectric layer 116. This allows for the spacers 126 to be formed with a reduced number of etch processes, which reduces costs and prevents damage to the underlying third dielectric layer 116. This reduces device defects and improves device performance.

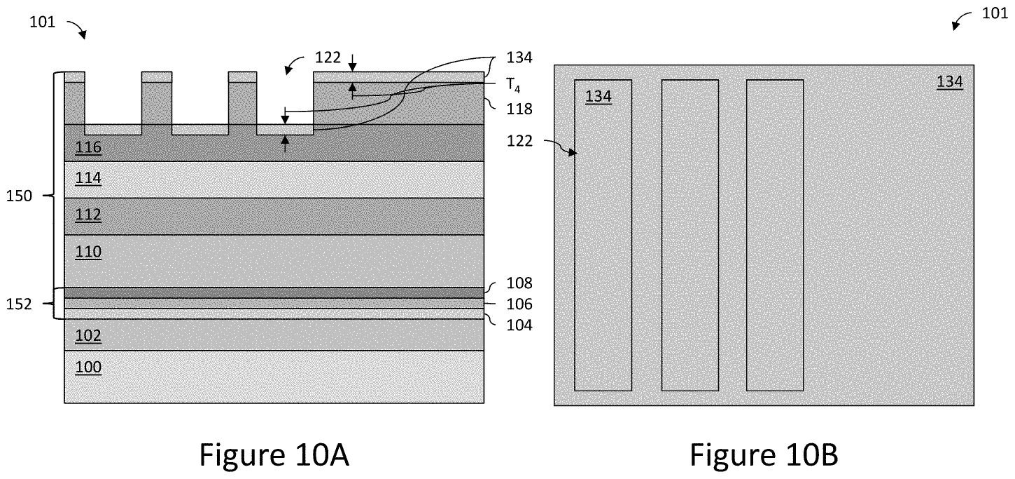

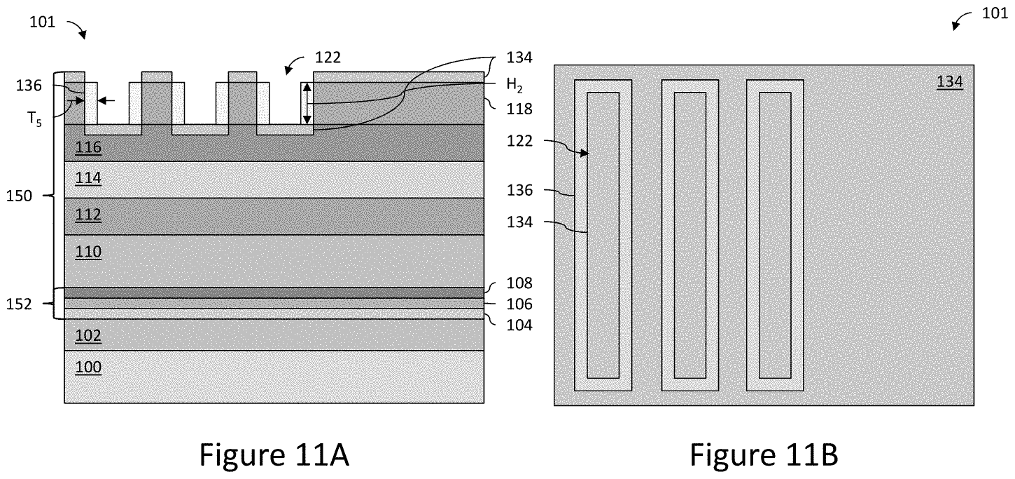

FIGS. 10A through 12B illustrate an embodiment in which a plasma treatment is performed on the second hard mask layer 118 and the third dielectric layer 116 to improve the selectivity of a deposition of spacers 136 (illustrated in FIGS. 11A and 11B), rather than using the selectivity-improving layer 124. FIGS. 10A and 10B illustrate the intermediate structures of FIGS. 2A and 2B after further processing.

In FIGS. 10A and 10B, a treated surface layer 134 is formed over the second hard mask layer 118 and the third dielectric layer 116. The top surfaces of the second hard mask layer 118 and the third dielectric layer 116 including the treated surface layer 134 may be referred to as modified top surfaces. As illustrated in FIGS. 10A and 10B, the treated surface layer 134 may be selectively deposited on top surfaces of the second hard mask layer 118 and exposed top surfaces of the third dielectric layer 116. The treated surface layer 134 may be formed by performing a plasma treatment process on the top surfaces of the second hard mask layer 118 and the exposed top surfaces of the third dielectric layer 116. In some embodiments, the plasma treatment process may include plasma formed from a fluorocarbon gas. The fluorocarbon gas may have a chemical formula CₓF_{y}, such as CF₂, C₄F₆, C₃F₈, CH₃F, CHF₃, or the like. The plasma treatment process may be performed at a temperature ranging from about 100° C. to about 400° C., a pressure ranging from about 1 Torr to about 4 Torr, with a plasma power ranging from about 50 W to about 1000 W, and with a bias voltage ranging from about 10 V to about 100 V. The plasma treatment may form the treated surface layer 134 on the top surfaces of the second hard mask layer 118 and the exposed top surfaces of the third dielectric layer 116. The treated surface layer 134 may comprise a fluorocarbon film having a thickness T₄ ranging from about 1 nm to about 3 nm.

In FIGS. 11A and 11B, spacers 136 are formed in the openings 122 along side surfaces of the second hard mask layer 118. The side surfaces of the second hard mask layer 118 may be adjacent to the openings 122. The treated surface layer 134 is unreactive to the deposition process used to deposit the spacers 136, such that the spacers 136 are selectively deposited along side surfaces of the second hard mask layer 118, which are free from the treated surface layer 134, without the spacers 136 being deposited along the treated surface layer 134 (e.g., along the top surfaces of the second hard mask layer 118 and the exposed top surfaces of the third dielectric layer 116). Specifically, the spacers 136 may be selectively deposited along the H-terminated silicon side surfaces of the second hard mask layer 118, without being deposited along the treated surface layer 134.

The spacers 136 may be formed of metal-containing materials, such as metal oxides, metal nitrides, or the like. In some embodiments, the spacers 136 may be formed of titanium oxide (TiO₂), titanium nitride, aluminum oxide (Al₂O₃) or the like. The spacers 136 may be deposited by an ALD process in which a first precursor and a second precursor are alternately supplied to the semiconductor device 101. The first precursor may include titanium chloride (TiCl₄, TC), titanium dichloride diethoxide (TiCl₂(OC₂H₅)₂, TDD), titanium ethoxide (Ti(OC₂H₅)₄, TE), tetrakis(dimethylamido)titanium (TDMAT, ((CH₃)₂N)₄Ti), other titanium-containing precursors, aluminum-containing precursors, combinations thereof, or the like. The second precursor may include water, ozone, hydrogen peroxide, combinations thereof, or the like. The spacers 136 may be deposited to a thickness T₅ ranging from about 1 nm to about 10 nm. In the embodiment illustrated in FIGS. 10A and 10B, the spacers 136 may have heights equal to a height of the second hard mask layer 118 (e.g., the thickness T₁). In some embodiments, the spacers 136 may have heights less than the height of the second hard mask 118. The spacers 136 may have heights H₂ ranging from about 10 nm to about 50 nm. As illustrated in FIGS. 10A and 10B, the spacers 136 may be separated from the third dielectric layer 116 by the treated surface layer 134.

Because the spacers 136 are selectively deposited only along sidewalls of the second hard mask layer 118, etching processes used to define the spacers 136 may be omitted. This reduces costs and reduces damage to underlying layers, such as the third dielectric layer 116. This further reduces device defects and improves device performance.

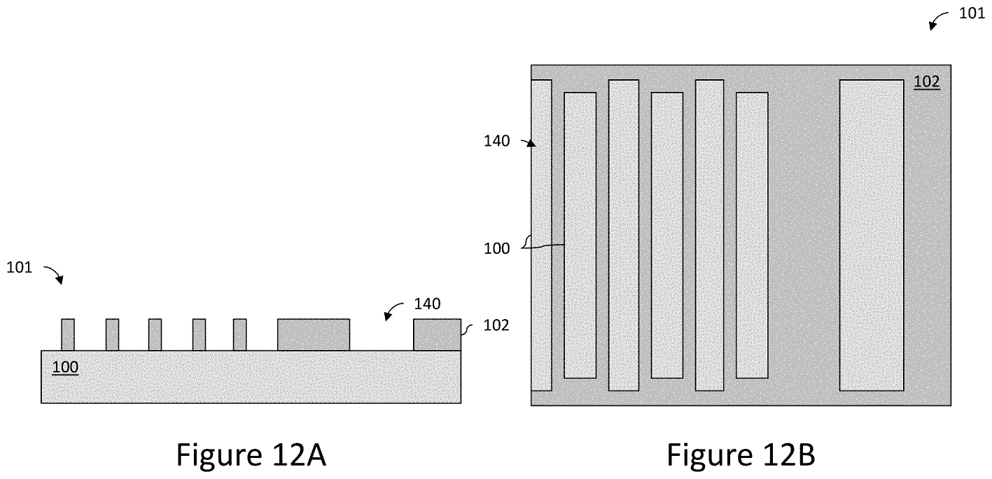

FIGS. 12A and 12B illustrate the intermediate structures of FIGS. 11A and 11B after processes the same as or similar to those described above with respect to FIGS. 5A through 9B are performed. The structure of FIGS. 12A and 12B may be substantially similar to the structure of FIGS. 9A and 9B.

Embodiments may achieve various advantages. For example, selectively depositing spacers 126/136 only along sidewalls of the second hard mask layer 118 allows for etching processes used to define the spacers 136 to be omitted. This reduces costs and reduces damage to underlying layers, such as the third dielectric layer 116. This further reduces device defects and improves device performance.

In accordance with an embodiment, a method includes forming a first dielectric layer over a semiconductor substrate; forming a first hard mask layer over the first dielectric layer; etching the first hard mask layer to form a first opening exposing a top surface of the first dielectric layer; performing a plasma treatment process on the top surface of the first dielectric layer and a top surface of the first hard mask layer; after performing the plasma treatment process, selectively depositing a spacer on a side surface of the first hard mask layer, the top surface of the first dielectric layer and the top surface of the first hard mask layer being free from the spacer after selectively depositing the spacer; and etching the first dielectric layer using the spacer as a mask. In an embodiment, the plasma treatment process includes a fluorocarbon-based plasma treatment. In an embodiment, the plasma treatment process includes an oxygen-based plasma treatment. In an embodiment, the method further includes forming a self-assembled monolayer over the top surface of the first dielectric layer and the top surface of the first hard mask layer after performing the plasma treatment process and before selectively depositing the spacer. In an embodiment, a precursor for the self-assembled monolayer includes octadecyltrichlorosilane. In an embodiment, the first dielectric layer includes silicon oxide, the first hard mask layer includes amorphous silicon, and the spacer includes titanium dioxide.

In accordance with another embodiment, a method includes depositing a mandrel layer over a first dielectric layer; forming a first opening extending through the mandrel layer to the first dielectric layer; depositing a selectivity-improving layer over a top surface of the first dielectric layer and a top surface of the mandrel layer, a side surface of the mandrel layer adjacent the first opening being free from the selectivity-improving layer; and selectively depositing a spacer on the side surface of the mandrel layer, a first height of the spacer being less than a second height of the mandrel layer. In an embodiment, the method further includes performing an oxygen-based plasma treatment on the top surface of the first dielectric layer and the top surface of the mandrel layer before depositing the selectivity-improving layer. In an embodiment, the selectivity-improving layer includes a self-assembled monolayer. In an embodiment, a precursor for the self-assembled monolayer includes octadecyltrichlorosilane. In an embodiment, the selectivity-improving layer includes a fluorocarbon film. In an embodiment, depositing the selectivity-improving layer over the top surface of the first dielectric layer and the top surface of the mandrel layer includes performing a plasma treatment on the top surface of the first dielectric layer and the top surface of the mandrel layer, and a precursor for the plasma treatment includes a fluorocarbon. In an embodiment, the method further includes etching the first dielectric layer using the spacer as a mask. In an embodiment, the spacer includes titanium oxide, and the mandrel layer includes amorphous silicon.

In accordance with yet another embodiment, a method includes depositing a first mask layer over a semiconductor substrate; etching the first mask layer to form a first opening extending through the first mask layer; performing a selectivity-modifying process on a top surface of the first mask layer to form a modified top surface; depositing a spacer over a side surface of the first mask layer adjacent the first opening using atomic layer deposition, the modified top surface being free from the spacer after the spacer is deposited; and removing the first mask layer. In an embodiment, the selectivity-modifying process includes exposing the top surface of the first mask layer to a plasma, and the plasma is formed from a first precursor including a fluorocarbon. In an embodiment, the selectivity-modifying process includes exposing the top surface of the first mask layer to a plasma, and the plasma is formed from oxygen. In an embodiment, the selectivity-modifying process further includes forming a self-assembled monolayer on the top surface of the first mask layer after exposing the top surface of the first mask layer to the plasma. In an embodiment, the self-assembled monolayer is formed from a precursor including octadecyltrichlorosilane. In an embodiment, the spacer includes titanium oxide, and the first mask layer includes amorphous silicon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first dielectric layer over a semiconductor substrate;
forming a first hard mask layer over the first dielectric layer;
etching the first hard mask layer to form a first opening exposing a top surface of the first dielectric layer;
performing a plasma treatment process on the top surface of the first dielectric layer and a top surface of the first hard mask layer;
after performing the plasma treatment process, selectively depositing a spacer on a side surface of the first hard mask layer, wherein the top surface of the first dielectric layer and the top surface of the first hard mask layer are free from the spacer after selectively depositing the spacer; and
etching the first dielectric layer using the spacer as a mask.

2. The method of claim 1, wherein the plasma treatment process comprises a fluorocarbon-based plasma treatment.

3. The method of claim 1, wherein the plasma treatment process comprises an oxygen-based plasma treatment.

4. The method of claim 3, further comprising forming a self-assembled monolayer over the top surface of the first dielectric layer and the top surface of the first hard mask layer after performing the plasma treatment process and before selectively depositing the spacer.

5. The method of claim 4, wherein a precursor for the self-assembled monolayer comprises octadecyltrichlorosilane.

6. The method of claim 1, wherein the first dielectric layer comprises silicon oxide, wherein the first hard mask layer comprises amorphous silicon, and wherein the spacer comprises titanium dioxide.

7. A method comprising:
depositing a mandrel layer over a first dielectric layer;
forming a first opening extending through the mandrel layer to the first dielectric layer;
depositing a selectivity-improving layer over a top surface of the first dielectric layer and a top surface of the mandrel layer, wherein a side surface of the mandrel layer adjacent the first opening is free from the selectivity-improving layer; and
selectively depositing a spacer on the side surface of the mandrel layer, wherein a first height of the spacer is less than a second height of the mandrel layer.

8. The method of claim 7, further comprising performing an oxygen-based plasma treatment on the top surface of the first dielectric layer and the top surface of the mandrel layer before depositing the selectivity-improving layer.

9. The method of claim 7, wherein the selectivity-improving layer comprises a self-assembled monolayer.

10. The method of claim 9, wherein a precursor for the self-assembled monolayer comprises octadecyltrichlorosilane.

11. The method of claim 7, wherein the selectivity-improving layer comprises a fluorocarbon film.

12. The method of claim 7, wherein depositing the selectivity-improving layer over the top surface of the first dielectric layer and the top surface of the mandrel layer comprises performing a plasma treatment on the top surface of the first dielectric layer and the top surface of the mandrel layer, and wherein a precursor for the plasma treatment comprises a fluorocarbon.

13. The method of claim 7, further comprising etching the first dielectric layer using the spacer as a mask.

14. The method of claim 7, wherein the spacer comprises titanium oxide, and wherein the mandrel layer comprises amorphous silicon.

15. A method comprising:
depositing a first mask layer over a semiconductor substrate;
etching the first mask layer to form a first opening extending through the first mask layer;
performing a selectivity-modifying process on a top surface of the first mask layer to form a modified top surface;
depositing a spacer over a side surface of the first mask layer adjacent the first opening using atomic layer deposition, wherein the modified top surface is free from the spacer after the spacer is deposited; and
removing the first mask layer.

16. The method of claim 15, wherein the selectivity-modifying process comprises exposing the top surface of the first mask layer to a plasma, and wherein the plasma is formed from a first precursor comprising a fluorocarbon.

17. The method of claim 15, wherein the selectivity-modifying process comprises exposing the top surface of the first mask layer to a plasma, and wherein the plasma is formed from oxygen.

18. The method of claim 17, wherein the selectivity-modifying process further comprises forming a self-assembled monolayer on the top surface of the first mask layer after exposing the top surface of the first mask layer to the plasma.

19. The method of claim 18, wherein the self-assembled monolayer is formed from a precursor comprising octadecyltrichlorosilane.

20. The method of claim 15, wherein the spacer comprises titanium oxide, and wherein the first mask layer comprises amorphous silicon.
